(19) United States
(12) Patent Application Publication
(10) Pub. No.: US 2026/0016758 A1
(43) Pub. Date: Jan. 15, 2026

(54) SEMICONDUCTOR PROCESS APPARATUS

(71) Applicant: Samsung Electronics Co., Ltd., Suwon-si (KR)

(72) Inventors: Jisu Kim, Suwon-si (KR); Hyeseon Kwon, Suwon-si (KR); Jangyeob Lee, Suwon-si (KR); Kuikam Kwon, Suwon-si (KR); Yunha Kim, Suwon-si (KR); Jeonggil Kim, Suwon-si (KR); Seungho Lee, Suwon-si (KR)

(21) Appl. No.: 19/011,855

(22) Filed: Jan. 7, 2025

(30) Foreign Application Priority Data
Jul. 11, 2024 (KR) 10-2024-0091589

(51) Int. Cl. G03F 7/00; G03F 7/20

(52) U.S. Cl. CPC G03F 7/70516; G03F 7/2006; G03F 7/70033; G03F 7/7085

(57) ABSTRACT

A semiconductor process apparatus includes a controller configured to receive a determination signal representing a first position at which a laser beam is expected to irradiate a first droplet, calculate a second position at which the laser beam irradiates the first droplet and generate a measurement signal representing the second position, generate at least one of first and second error signals from the determination signal and the measurement signal, generate a feedforward signal from at least one of the first error signal and the second error signal, generate a feedback signal from the feedforward signal and a first position difference in the first direction between the first and second positions, and determine a second emission time point for a second specific period in which a second droplet is supplied by adding the feedback signal to a reference signal.

### CROSS-REFERENCE TO RELATED APPLICATION(S)

This application claims benefit of priority to Korean Patent Application No. 10-2024-0091589 filed on Jul. 11, 2024 in the Korean Intellectual Property Office, the disclosure of which is incorporated herein by reference in its entirety.

### BACKGROUND

Example embodiments of the present disclosure relate to a semiconductor process apparatus.

A semiconductor process may include a photolithography process, an etching process, a deposition process, or the like, to form a plurality of layers on a substrate, and a plurality of patterns may be formed in each of the plurality of layers. As a line width of the plurality of patterns becomes fine and a spacing therebetween becomes narrower, a photolithography process using light of a relatively short wavelength band, such as extreme ultraviolet (EUV) light, has been suggested. A semiconductor process apparatus performing a photolithography process using extreme ultraviolet light may include a light source system generating extreme ultraviolet light. To improve and stably maintain yield and productivity of a semiconductor process performed in the semiconductor process apparatus, it may be necessary to improve a magnitude of energy of extreme ultraviolet light generated by the light source system.

### SUMMARY

An example embodiment of the present disclosure is to provide a semiconductor process apparatus which may generate extreme ultraviolet light having an improved magnitude of energy by controlling a time point at which a laser beam is irradiated to a droplet.

According to an aspect of the present disclosure, a semiconductor process apparatus include a droplet supplier configured to form a first droplet and to supply the first droplet to a chamber in a first direction and in a first specific period, a light source generator configured to emit a laser beam in a second direction perpendicular to the first direction at a first emission time point such that extreme ultraviolet light is generated from the first droplet, a position sensor disposed adjacently to the chamber, and a controller configured to receive a determination signal including a first information representing a first position at which the laser beam is expected to irradiate the first droplet, calculate a second position at which the laser beam irradiates the first droplet using an output of the position sensor and generate a measurement signal including a second information representing the second position, generate at least one of a first error signal and a second error signal from the determination signal and the measurement signal, generate a feedforward signal from at least one of the first error signal and the second error signal, generate a feedback signal from the feedforward signal and a first position difference in the first direction between the first position and the second position, and determine a second emission time point for a second specific period in which the droplet supplier supplies a second droplet into the chamber by adding the feedback signal to a reference signal including an information representing a reference time point in the first specific period.

According to an aspect of the present disclosure, a semiconductor process apparatus includes a droplet supplier configured to form a droplet and to supply the droplet to a chamber in a first direction, a light source generator configured to emit a laser beam in a second direction perpendicular to the first direction at a first emission time point such that extreme ultraviolet light is generated from the droplet, a position sensor disposed adjacently to the chamber, and a controller configured to receive a determination signal including an information representing a first position at which the droplet is determined to be irradiated with the laser beam and to determine a second emission time point. The controller is further configured to calculate a measurement signal including an information representing a second position at which the droplet is irradiated with the laser beam using an output of the position sensor, and to generate an error signal including an information representing a difference between the first position of the determination signal and the second position of the measurement signal. The determination signal, the measurement signal, and the error signal include position values in the first direction, the second direction, and a third direction perpendicular to the first direction and the second direction in a specific period, respectively. The controller is further configured to calculate a position compensation value in the first direction using at least one of a position value in the second direction of the error signal and a position value in the third direction of the error signal. The second emission time point is determined using a position value in the first direction of the determination signal, a position value in the first direction of the measurement signal, and a position compensation value in the first direction.

According to an aspect of the present disclosure, a semiconductor process apparatus includes a droplet supplier configured to form a droplet and to supply the droplet to a chamber in a first direction, a light source generator configured to emit a laser beam in a second direction perpendicular to the first direction at a first emission time point such that extreme ultraviolet light is generated from the droplet, a position sensor disposed adjacently to the chamber, and a controller configured to receive a determination signal including an information representing a first position at which the droplet is determined to be irradiated with the laser beam and to determine a second emission time point. The controller is further configured to calculate a measurement signal including an information representing a second position at which the droplet is irradiated with the laser beam using an output of the position sensor, and to calculate an error signal including an information representing a difference between the first position of the determination signal and the second position of the measurement signal. The determination signal, the measurement signal, and the error signal include position values in the first direction, the second direction, and a third direction perpendicular to the first direction and the second direction in a specific period, respectively. A position value in the first direction of the determination signal is controlled such that energy of extreme ultraviolet light increases at a position value in the second direction of the measurement signal and at a position value in the third direction of the measurement signal by determining the second emission time point using position values in the first to third directions of the error signal.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a semiconductor process apparatus according to an example embodiment of the present disclosure;

FIG. 2 is a diagram illustrating a light source system according to an example embodiment of the present disclosure;

FIG. 3 is an enlarged diagram illustrating region “A” illustrated in FIG. 2;

FIG. 4 is a block diagram illustrating a semiconductor process apparatus according to an example embodiment of the present disclosure;

FIG. 5 is a flowchart illustrating a process of controlling an oscillation time point of a semiconductor process apparatus according to an example embodiment of the present disclosure;

FIG. 6 is a diagram illustrating position values in first to third directions according to an example embodiment of the present disclosure;

FIGS. 7 and 8 are block diagrams illustrating a semiconductor process apparatus according to example embodiments of the present disclosure;

FIG. 9 is a diagram illustrating a compensation function included in a feedforward compensator according to an example embodiment of the present disclosure;

FIG. 10 is a diagram illustrating application of a compensation function according to an example embodiment illustrated in FIG. 9 of the present disclosure;

FIG. 11 is a diagram illustrating dispersion of energy of extreme ultraviolet light output by a light source generator including a compensation function according to an example embodiment illustrated in FIG. 9 of the present disclosure;

FIG. 12 is a diagram illustrating a compensation function included in a feedforward compensator according to an example embodiment of the present disclosure;

FIG. 13 is a diagram illustrating application of a compensation function according to an example embodiment illustrated in FIG. 9 of the present disclosure;

FIG. 14 is a diagram illustrating dispersion of energy of extreme ultraviolet light output by a light source generator including a compensation function according to an example embodiment of the present disclosure;

FIG. 15 is a block diagram illustrating a semiconductor process apparatus according to an example embodiment of the present disclosure;

FIG. 16 is a diagram illustrating magnitude of energy of extreme ultraviolet light according to an example embodiment of the present disclosure; and

FIG. 17 is a diagram illustrating calculation of an oscillation time point according to an example embodiment of the present disclosure.

### DETAILED DESCRIPTION

Hereinafter, embodiments of the present disclosure will be described as follows with reference to the accompanying drawings.

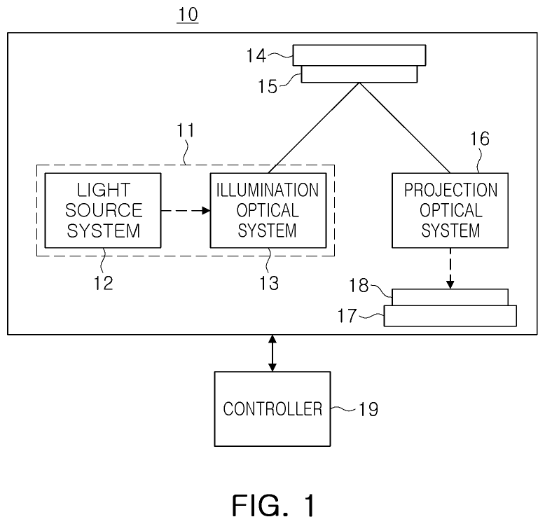

FIG. 1 is a diagram illustrating a semiconductor process apparatus according to an example embodiment.

Referring to FIG. 1, a semiconductor process apparatus 10 according to an example embodiment may be implemented as an apparatus performing a photolithography process, and may include an illumination unit 11, a mask stage 14, a projection optical system 16, a substrate stage 17, and a controller 19.

The illumination unit 11 may include a light source system 12 and an illumination optical system 13, and the light source system 12 may generate and output extreme ultraviolet light having a high energy density within a wavelength band range of several nanometers to several tens of nanometers. In an example embodiment, the light source system 12 may generate and output extreme ultraviolet light having a high energy density in a wavelength band of 13.5 nm. The light source system 12 may include a plasma-based light source or a synchrotron radiation light source.

As an example, the light source system 12 may output extreme ultraviolet light using plasma. The light source may operate in a laser-produced plasma (LPP) mode in which a high-output laser beam is irradiated to a droplet formed of one of materials such as tin, lithium, and xenon to generate plasma, or in a discharge-produced plasma (DPP) mode, or in a master oscillator power amplifier (MOPA) mode.

Plasma may be formed by irradiating droplets supplied by the droplet supplier with a laser beam. Accordingly, the light source system 12 may include an illumination mirror and a light collection mirror for refocusing extreme ultraviolet light formed by the plasma. The light collection mirror may function as a reflector and may be disposed close to the droplets to increase the refocusing efficiency. The energy density of extreme ultraviolet light output by the light source system 12 may be increased by the illumination mirror and the light collection mirror.

The illumination optical system 13 may include a plurality of illumination mirrors. In the semiconductor process apparatus 10 according to an example embodiment, the illumination optical system 13 may include two or more illumination mirrors. The illumination optical system 13 may transfer extreme ultraviolet light emitted by the light source system 12 to a mask stage 14. The extreme ultraviolet light emitted by the light source system 12 may be reflected by the illumination mirrors included in the illumination optical system 13 and may be incident to a mask 15 seated on the mask stage 14.

In an example embodiment, the mask 15 may be a reflective mask including a non-reflective region and/or an intermediate reflective region together with a reflective region. The mask 15 may include a reflective multilayer film for reflecting extreme ultraviolet light on a substrate formed of a low thermal expansion coefficient material (LTEM) such as quartz, and an absorption layer pattern formed on the reflective multilayer film. The reflective multilayer film may have a structure in which layers formed of different materials are stacked. The absorption layer may be formed of TaN, TaNO, TaBO, Ni, Au, Ag, C, Te, Pt, Pd, Cr, or the like. However, a material of the absorption layer is not limited to the materials described above, and the absorption layer portion may correspond to the non-reflective region and/or the intermediate reflective region described above.

The mask 15 may reflect extreme ultraviolet light incident to the illumination optical system 13 and may allow extreme ultraviolet light to be incident to the projection optical system 16. The projection optical system 16 may be implemented as an imaging optical system disposed between the mask stage 14 and the substrate stage 17. For example, the extreme ultraviolet light passing through the illumination optical system 13 may be structured according to a pattern shape including a reflective multilayer film and an absorption layer on the substrate in the mask 15 and may be incident to the projection optical system 16.

The extreme ultraviolet light may be structured to include at least second-order diffraction light based on the pattern on the mask 15. The structured extreme ultraviolet light may be incident to the projection optical system 16 while retaining information on the pattern shape included in the mask 15, and may be irradiated to the substrate 18 seated on the substrate stage 17 through the projection optical system 16 such that an image corresponding to the pattern shape included in the mask 15 may be formed. For example, the structured extreme ultraviolet light may be irradiated to a photoresist layer coated on the substrate 18 and may form a specific pattern in the photoresist layer. However, in example embodiments, the structured extreme ultraviolet light passing through the projection optical system 16 may be incident to a process target other than the substrate 18.

The extreme ultraviolet light reflected from the mask 15 and passing through the projection optical system 16 may be incident to an upper surface of the substrate 18 at a specific slope. For example, the projection optical system 16 may adjust a traveling path of extreme ultraviolet light such that extreme ultraviolet light may be incident to an upper surface of the substrate 18 at an incident angle of about 6 degrees.

The mask 15 may be seated on the mask stage 14, and the substrate 18 may be seated on the substrate stage 17. For example, the mask stage 14 and the substrate stage 17 may be controlled by the controller 19. In an initial state in which the mask 15 and the substrate 18 are seated on the mask stage 14 and the substrate stage 17, respectively, when upper surfaces of the mask 15 and the substrate 18 are defined as an x-y plane, the mask stage 14 and the substrate stage 17 may move by the controller 19. In an example embodiment, the controller 16 may rotate the mask stage 14 and the substrate stage 17 on the x-y plane with respect to a Z-axis, or on a y-z plane or a x-z plane with respect to one axis on the x-y plane. By the movement of the mask stage 14 and/or the substrate stage 17 described above, the mask 15 and/or the substrate 18 may move or rotate along the X-axis, the Y-axis, and the Z-axis in three-dimensional space.

The projection optical system 16 may include a plurality of projection mirrors. Each of the plurality of projection mirrors included in the projection optical system 16 may include a mirror body, and a reflective layer attached to a surface of the mirror body. As described above, extreme ultraviolet light passing through the illumination optical system 13 and reflected by the mask 15 may be structured and incident to the projection optical system 16, and accordingly, each of the plurality of projection mirrors may reflect the structured extreme ultraviolet light.

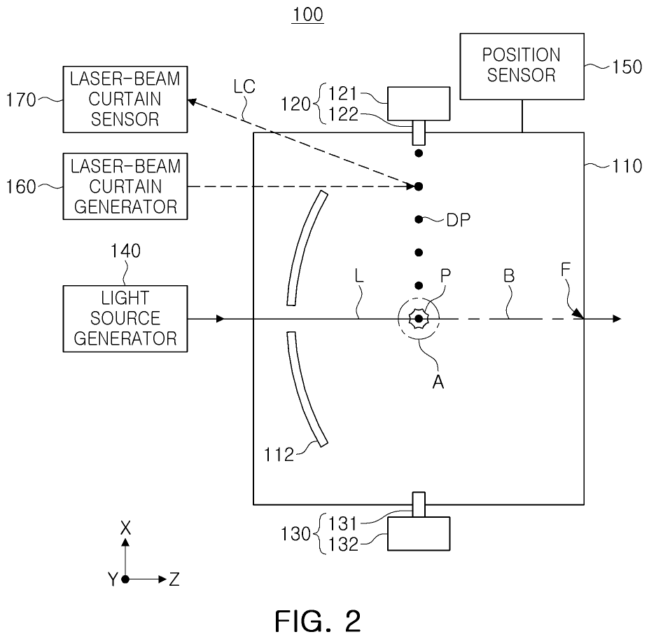

According to an example embodiment, the controller 19 may control an oscillation time point of the laser beam using a position at which the droplet is irradiated with the laser beam. For example, the oscillation time point of the laser beam may correspond to a time at which a laser source generator 140, which will be described with reference to FIG. 2, emits the laser beam to irradiate the droplet, which may be referred to as a shooting time of the laser beam or as an emission time point of the laser beam. Accordingly, at the time point at which the laser beam is irradiated to the droplet, a distance between the droplet and a central axis of the laser beam may be controlled. In this case, the distance between the droplet and the central axis of the laser beam may be relative to the emission direction of the droplet.

Accordingly, an average size of energy of the generated extreme ultraviolet light may be improved, and dispersion of energy of extreme ultraviolet light may be reduced. The semiconductor process time may be shortened, such that productivity may be improved.

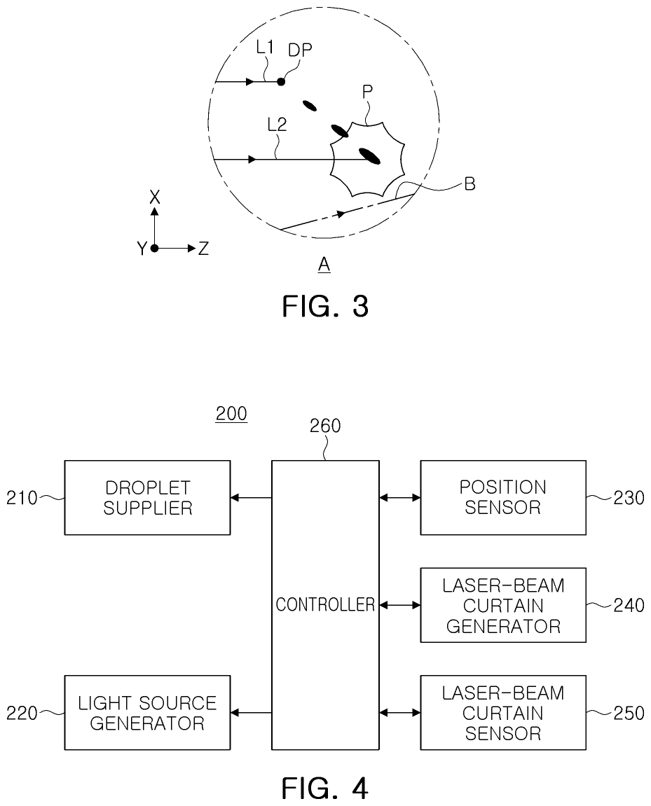

FIG. 2 is a diagram illustrating a light source system according to an example embodiment. FIG. 3 is an enlarged diagram illustrating region “A” illustrated in FIG. 2.

Referring to FIG. 2, a light source system 100 in an example embodiment illustrated in FIG. 2 may generate and output extreme ultraviolet light B. The light source system 100 may operate by an LPP manner to generate plasma P by irradiating a laser beam L to a droplet DP. However, an example embodiment thereof is not limited thereto.

The light source system 100 according to an example embodiment may include a chamber 110, a droplet supplier 120, a catcher 130, a light source generator 140, a position sensor 150, a laser-beam curtain generator 160, and a laser-beam curtain sensor 170.

The chamber 110 may be filled with hydrogen gas (H2 gas) and oxygen gas (O2 gas) at an ultra-low pressure. To prevent the extreme ultraviolet light B generated in the chamber 110 from being absorbed by gas in the chamber 110, the internal portion of the chamber 110 may be maintained at an ultra-low pressure. A focusing point F providing a path for emitting the extreme ultraviolet light B may be disposed on one side of the chamber 110.

The chamber 110 may include a light collection mirror 112. The light collection mirror 112 may focus the extreme ultraviolet light B toward the focusing point F. The light collection mirror 112 may be a major axis ellipsoid mirror having a first focus in a region in which the droplet DP is irradiated with the laser beam L or in a region adjacent thereto, and a second focus at the focusing point F.

A light source generator 140 configured to emit the laser beam L may be disposed on one surface of the light collection mirror 112. An optical aperture may be disposed in the central portion of the light collection mirror 112, such that the amount of irradiation of the laser beam L emitted from the light source generator 140 may be controlled. A reflective layer may be formed on the other surface of the light collection mirror 112 to enhance reflectivity of extreme ultraviolet light B, and the reflective layer may include multiple thin film layers in which molybdenum-silicon (Mo—Si) are cross-stacked.

The droplet supplier 120 may supply droplet DP for generating extreme ultraviolet light B in the chamber 110. The droplet supplier 120 may include a droplet supply source 121 and a droplet discharge portion 122.

The droplet supply source 121 may supply a target material for forming the droplet DP. The target material may be formed of a material among materials such as tin, lithium, and xenon. The droplet DP may be formed by liquefying a target material, or the liquid material may contain solid particles of the target material.

The droplet DP may be discharged through the droplet discharge portion 122 by pressurizing the target material stored in the droplet supply source 121. In this case, the droplet DP may be discharged in the first direction (the X-axis direction in FIGS. 2 and 3), and specifically, the droplet DP may be discharged in the −X-axis direction in FIGS. 2 and 3. The droplet DP discharged through the droplet discharge portion 122 may reach the internal region of the chamber 110 at a speed of about 20 to 70 m/s and a time interval of about 20 μs. However, the speed and period of the droplet DP may not be limited thereto.

The light source generator 140 may emit a laser beam L irradiated to the droplet DP. The light source generator 140 may be a driver light source and may emit a laser beam L in the second direction (Z-axis direction in FIGS. 2 and 3). The laser beam L may be provided in the form of a pulse wave.

Referring to FIGS. 2 and 3 together, the laser beam L may include a first laser beam L1 and a second laser beam L2. For example, the first laser beam L1 may correspond to a pre-pulse, and the second laser beam L2 may correspond to a main-pulse. The first laser beam L1 may increase a surface area of the droplet DP in advance before the second laser beam L2 is absorbed and interacts with the droplet DP, thereby increasing the conversion efficiency. In this case, the conversion efficiency may be a ratio of input power of the laser beam L emitted from the light source generator 140 to the output power of the emitted extreme ultraviolet light B.

As an example embodiment illustrated in FIG. 3, after a droplet DP is discharged from the droplet discharge portion 122, the droplet DP may be irradiated with a first laser beam L1 and may expand into a pancake shape. Thereafter, the droplet DP may be irradiated with a second laser beam L2, and the droplet DP irradiated with the second laser beam L2 may explode and may emit plasma P. The extreme ultraviolet light (not illustrated) radiated omnidirectionally from the plasma P may be collected as extreme ultraviolet light B by the light collection mirror 112.

Referring to FIG. 2, the catcher 130 may be disposed to face the droplet supplier 120 and may receive the droplet DP discharged from the droplet supplier 120. The catcher 130 may include a nozzle portion 131 and a vacuum source 132. The nozzle portion 131 may be disposed to face the droplet discharge portion 122. The vacuum source 132 may provide a vacuum pressure lower than atmospheric pressure in the chamber 110 such that the chamber 110 droplet DP may be suctioned through the nozzle portion 131.

The position sensor 150 may be disposed adjacently to the chamber 110. In an example embodiment illustrated in FIG. 2, the position sensor 150 may also be disposed adjacently to the droplet supplier 120. The position sensor 150 may correspond to at least one of a quad-cell sensor and an image sensor. However, the position and/or type of the position sensor 150 may not be limited thereto.

The position sensor 150 may be used to measure a position at which the droplet DP is irradiated with the laser beam L. The controller 19 in FIG. 1 may calculate a measurement signal indicating a position at which a droplet DP is irradiated with the laser beam L using an output of the position sensor 150. For example, the measurement signal may include an information representing the position at which the laser beam L irradiate the droplet DP, and a plasma light is generated at the position. A measurement signal may include position values in the first direction, the second direction, and the third direction (the Y-axis direction in FIG. 2 and FIG. 3) in a specific period. In this case, the specific period may be a period in which the droplet DP is emitted. In an embodiment, a single droplet is emitted during the specific period.

The laser-beam curtain generator 160 may generate a laser beam curtain LC. As an example embodiment illustrated in FIG. 2, the laser beam curtain LC may be formed to extend to a plane defined by the second direction and the third direction (the Y-Z plane in FIG. 2). The laser beam curtain LC may be formed between the droplet supplier 120 and the laser beam L. When the droplet DP passes through the laser beam curtain LC, the laser beam curtain LC may be reflected from the droplet DP.

The laser-beam curtain sensor 170 may sense the reflected laser beam curtain LC. The time point at which the laser-beam curtain sensor 170 senses the reflected laser beam curtain LC may correspond to a reference time point. According to an example embodiment, the time point at which the light source generator 140 emits the laser beam L may be calculated based on the reference time point.

According to an example embodiment, the oscillation time point may be controlled using position values in the first direction, the second direction, and the third direction of the measurement signal in a specific period. Accordingly, the distance between the droplet and the laser beam in the first direction may be controlled at the time point at which the laser beam is irradiated to the droplet. Accordingly, an average size of energy of the generated extreme ultraviolet light may be improved, and dispersion of energy of extreme ultraviolet light may be reduced. Accordingly, the semiconductor process time may be shortened, and accordingly, productivity may be improved.

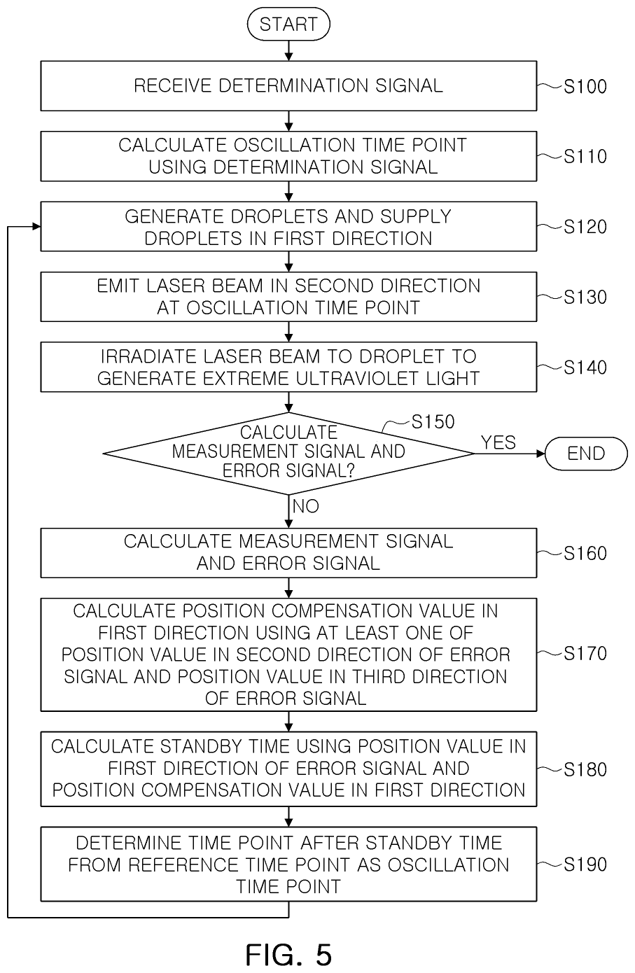

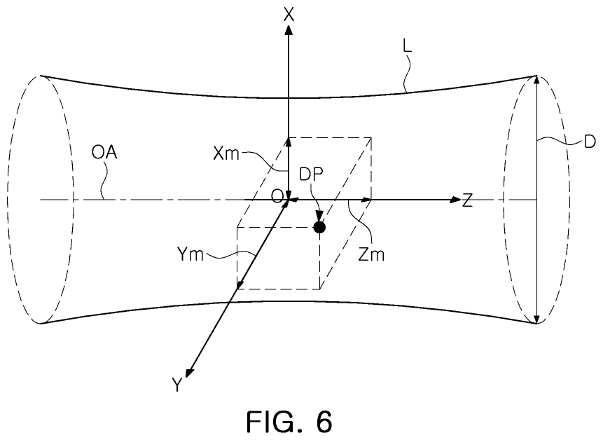

FIG. 4 is a block diagram illustrating a semiconductor process apparatus according to an example embodiment. FIG. 5 is a flowchart illustrating a process of controlling an oscillation time point of a semiconductor process apparatus according to an example embodiment. FIG. 6 is a diagram illustrating position values in first to third directions according to an example embodiment.

The semiconductor process apparatus 200 may be an apparatus performing a photolithography process, and may include an illumination unit, a mask stage, a projection optical system, a substrate stage, and a controller 260. The illumination unit may include a light source system 210-250 and an illumination optical system. The light source system 210-250 may generate and output extreme ultraviolet light. Specific example embodiments of the semiconductor process apparatus 200 may be similar to the examples described with reference to FIG. 1.

First, referring to FIG. 4, the light source system 210-250 according to an example embodiment may include a chamber (not illustrated), a droplet supplier 210, a light source generator 220, and a position sensor 230. The light source system 210-250 may further include a laser-beam curtain generator 240 and a laser-beam curtain sensor 250. Specific example embodiments of the light source system 210-250 may be similar to the examples described with reference to FIGS. 2 and 3.

The droplet supplier 210 may form a droplet and may supply the droplet to the internal region of the chamber in a first direction. The light source generator 220 may emit a laser beam in a second direction perpendicular to the first direction at an oscillation time point such that extreme ultraviolet light may be generated from the droplet. The position sensor 230 may be disposed adjacently to the chamber. However, the position of the position sensor 230 may not be limited thereto.

The laser-beam curtain generator 240 may emit a laser beam curtain in the second direction. The laser-beam curtain sensor 250 may sense the laser beam curtain reflected from the droplet when the droplet passes through the laser beam curtain. The controller 260 may determine a time point at which the laser beam curtain sensor 250 senses the reflected laser beam curtain as a reference time point, and may generate a reference signal including the reference time point in a specific period.

The controller 260 may determine an oscillation time point using a determination signal indicating a position at which a droplet is determined to be irradiated with the laser beam. For example, the determination signal may include an information representing a position at which the laser beam is determined to irradiate the droplet DP. Hereinafter, a process in which the controller 260 controls the oscillation time point will be described with reference to FIGS. 4 and 5.

The controller 260 may receive a determination signal indicating a position at which a droplet is determined to be irradiated with the laser beam (S100). The controller 260 may calculate an oscillation time point at which the laser beam is emitted using the determination signal (S110). The oscillation time point may be calculated based on a distance in the first direction between the droplet DP and the laser beam L.

The droplet supplier 210 may generate droplets and may supply the droplets to the internal region of the chamber in the first direction (S120). Specifically, the droplet supplier 210 may discharge a droplet through the discharge portion by pressurizing the received target material, and the droplet may be discharged in the first direction.

The controller 260 may control the light source generator 220, and the controller 260 may control the light source generator 220 to emit a laser beam at the calculated oscillation time point. In other words, the light source generator 220 may emit a laser beam in the second direction perpendicular to the first direction at the oscillation time point (S130).

The laser beam may be irradiated to the droplet to generate extreme ultraviolet light (S140). Specifically, the droplet may be supplied in the first direction, and the laser beam emitted in the second direction may be irradiated to the droplet to generate the plasma. The extreme ultraviolet light radiated omnidirectionally from the plasma may be collected and output. The extreme ultraviolet light generated in the light source system 210-250 may pass through the illumination optical system, the mask stage, and the projection optical system and may be irradiated to the substrate, thereby performing a semiconductor process. In this case, according to an example embodiment, the semiconductor process may be a process using extreme ultraviolet light, and may be, for example, a photolithography process.

After the droplet is irradiated with a laser beam and extreme ultraviolet light is irradiated, it may be determined whether the semiconductor process using extreme ultraviolet light is terminated (S150). When it is determined that the semiconductor process using extreme ultraviolet light is terminated in operation S150, operations S100 to S140 may not be repeated. When it is determined that the semiconductor process using extreme ultraviolet light is not terminated in operation S150, the oscillation time point may be modified (S160 to S190), and the process of generating extreme ultraviolet light at the modified oscillation time point by irradiating the droplet with a laser beam (S120 to S140) may be performed.

The controller 260 may calculate a measurement signal and an error signal (S160). The controller 260 may calculate a measurement signal indicating a position at which a droplet is irradiated with a laser beam using an output of the position sensor 230. The controller 260 may calculate an error signal as a difference between the determination signal and the measurement signal. For example, the error signal may include information representing a difference between a position represented by the determination signal and a position represented by the measurement signal.

Each of the determination signal, the measurement signal, and the error signal may include a position value in the first direction, a position value in the second direction, and a position value in a third direction perpendicular to the first direction and the second direction in a specific period.

The specific period may correspond to a period in which a droplet is discharged. Hereinafter, the position values in the first to third directions of the determination signal, the measurement signal, and the error signal will be described.

Referring to FIG. 6, the first direction may correspond to a direction in which a droplet DP emitted from the droplet supplier 210 travels. For example, the first direction may be the −X-axis direction in FIG. 6. The second direction may correspond to the direction in which the laser beam L emitted from the light source generator 220 travels, and the second direction may be the Z-axis direction in FIG. 6. Specifically, the laser beam L may be emitted linearly, and the optical axis OA of the laser beam L may coincide with the Z-axis. The third direction may be the Y-axis direction in FIG. 6.

An origin O in FIG. 6 may be a point at which the X-axis and the Z-axis intersect. According to an example embodiment, the origin O in FIG. 6 may be an intersection point at which the direction in which the droplet DP is emitted and the direction in which the laser beam is emitted intersect. Specifically, referring to FIG. 2 together, the origin O may coincide with a first focus of the light collection mirror 112. When the center of the laser beam L is the origin O, the diameter D of the laser beam L may be the smallest.

The diameter D of the laser beam L may be larger than a size of the droplet DP. Accordingly, the droplet DP may be irradiated with the laser beam L at points defined at different coordinates within the laser beam L.

The position values in the first to third directions may be a relative distance to the origin O in FIG. 6. According to an example embodiment, FIG. 6 may indicate a position at which the droplet DP is irradiated with the laser beam L. The position at which the droplet DP is irradiated with the laser beam L may be a relative distance to the origin O. The position at which the droplet DP is irradiated with the laser beam L may be defined by coordinates. In an embodiment, the position represented by the determination signal may initially correspond to the origin O for a droplet supplied for the first time among a plurality of droplets sequentially generated by a droplet supplier 120 which will be described with reference to FIG. 2, and for the irradiation of the laser light to the next droplet, the position represented by the determination signal may be updated using a difference between a position represented by the measurement signal of the first droplet and a position (e.g., the origin O) of the determination signal. For example, a laser source generator 140, which will be described with reference to FIG. 2, may be controlled such that the laser light is emitted toward the updated position. For example, the direction along which the laser light is emitted toward the current droplet may be determined using a measurement signal of the previous droplet.

The coordinates for the position at which the droplet DP is irradiated with the laser beam L may include a position value Xm in the first direction, a position value Zm in the second direction, and a position value Ym in the third direction. That is, the measurement signal may include a position value Xm in the first direction, a position value Zm in the second direction, and a position value Ym in the third direction in a specific period. The position values Xm, Zm, and Ym in the first to third directions may be positive values, but an example embodiment thereof is not limited thereto.

The determination signal may represent a position at which the droplet DP is determined to be irradiated with laser beam L in a specific period, and the position may be defined by a coordinate. Although not illustrated in FIG. 6, the coordinates of the position at which the droplet DP is determined to be irradiated with the laser beam L may include a position value Xs in the first direction, a position value Zs in the second direction, and a position value Ys in the third direction. That is, the determination signal may include the position value Xs in the first direction, the position value Zs in the second direction, and the position value Ys in the third direction in a specific period.

The error signal may be a difference between the determination signal and the measurement signal. Although not illustrated in FIG. 6, the error signal may include a position value Xe in the first direction, a position value Ze in the second direction, and a position value Ye in the third direction in a specific period. In a specific period, the position value Xe in the first direction of the error signal may be an error between the position value Xs in the first direction of the determination signal and the position value Xm in the first direction of the measurement signal.

The position value Ze in the second direction of the error signal may be an error between the position value Zs in the second direction of the determination signal and the position value Zm in the second direction of the measurement signal. The position value Ye in the third direction of the error signal may be an error between the position value Ys in the third direction of the determination signal and the position value Ym in the third direction of the measurement signal.

The controller 260 may calculate the position compensation value in the first direction using at least one of the position value Ze in the second direction of the error signal and the position value Ye in the third direction of the error signal (S170). The position compensation value in the first direction may compensate for the position value Xs in the first direction of the determination signal. In other words, the position value Xs in the first direction may be changed using at least one of the position value Ze in the second direction of the error signal and the position value Ye in the third direction of the error signal.

The controller 260 may calculate a standby time using the position value Xe in the first direction of the error signal and the position compensation value in the first direction. Specifically, the standby time may be calculated using the position value Xs in the first direction of the determination signal, the position value Xm in the first direction of the measurement signal, and the position compensation value in the first direction. The light source generator 220 of FIG. 4 may emit the laser light at the standby time after the droplet is detected to enter the laser-beam curtain formed on a plane defined by the Y-axis and the Z-axis. For example, the light source generator 220 may emit the laser light in a pulse at a specific period.

The controller 260 may determine a time point after the standby time from the reference time point as an oscillation time point (S190), and may perform a process of irradiating the droplet with a laser beam at the determined oscillation time point and generating extreme ultraviolet light (S120 to S140).

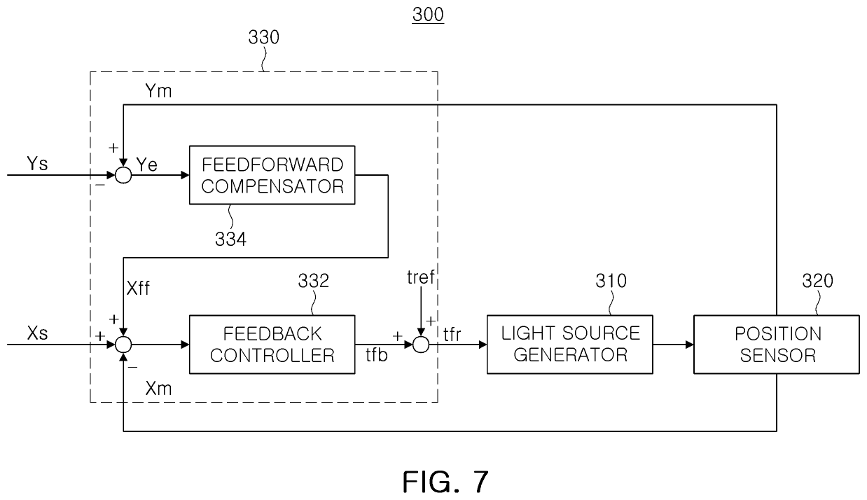

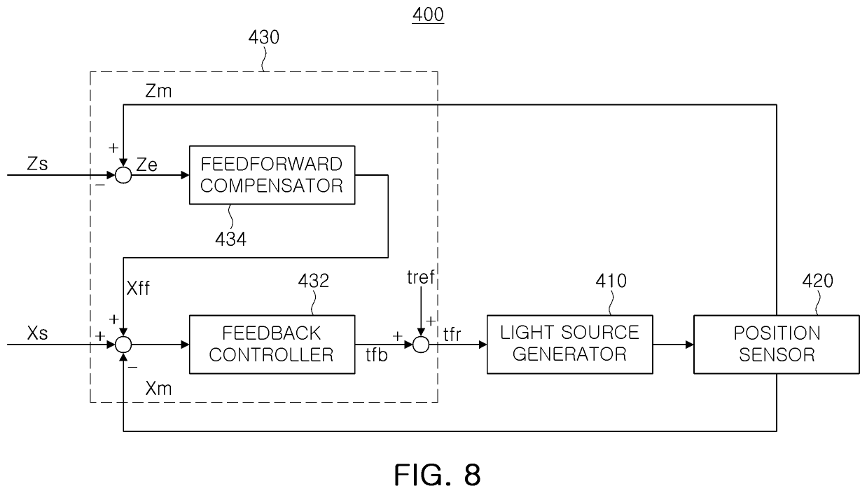

FIGS. 7 and 8 are block diagrams illustrating a semiconductor process apparatus according to example embodiments.

The semiconductor process apparatuses 300 and 400 may include a light source generator 310, 410, position sensors 320 and 420, and controllers 330 and 430. Specific example embodiments of the semiconductor process apparatuses 300 and 400 may be similar to the examples described with reference to FIGS. 1 to 6.

The controllers 330 and 430 may receive a determination signal indicating a position at which a droplet is determined to be irradiated with a laser beam. The determination signal may include position values Xs, Zs, and Ys in the first to the third directions, respectively, in a specific period.

The controllers 330 and 430 may generate a reference signal tref, which may be a reference for the oscillation time point tfr. Specifically, referring to FIG. 2, the controllers 330 and 430 may determine a time point at which the laser-beam curtain sensor 170 senses the reflected laser beam curtain LC as a reference time point. The reference signal tref may include a reference time point in a specific period.

The controllers 330 and 430 may calculate a measurement signal indicating a position at which a droplet is irradiated with a laser beam using the output signal of the position sensors 320 and 420. The measurement signal may include position values Xm, Zm, and Ym in the first to the third directions in the specific period.

The controllers 330 and 430 may calculate an error signal using the determination signal and the measurement signal. For example, the error signal may correspond to a difference between the determination signal and the measurement signal. The error signal may include position values Xe, Ze, and Ye in the first to the third directions in the specific period.

Each of the determination signal, the reference signal, the measurement signal, and the error signal may correspond to a discrete time signal having position values in the first to third directions at an interval of specific period. In this case, the specific period may be the same as the period in which the droplet is discharged. For example, the droplet supplier 120 may be controlled to sequentially discharge each of a plurality of droplets into a space defined by the chamber 110 in the specific period. However, an example embodiment thereof is not limited thereto.

According to an example embodiment, the semiconductor process apparatuses 300 and 400 may include feedback controllers 332 and 432 generating a feedback signal tfb and feedforward compensators 334 and 434 generating a feedforward signal Xff.

According to an example embodiment, the feedback controllers 332 and 432 may receive the feedforward signal Xff, the position value Xs in the first direction of the determination signal, and the position value Xm in the first direction of the measurement signal in a specific period and may output the feedback signal tfb. In other words, the feedback controllers 332 and 432 may generate a feedback signal tfb by feedback-controlling a first signal obtained by adding a feedforward signal Xff to a difference between the position value Xs in the first direction of the determination signal in a specific period and the position value Xm in the first direction of the measurement signal. For example, the feedback controllers 332 and 432 may receive the first signal and generate the feedback signal tfb from the first signal and a traveling speed of the droplet. In this case, the feedback signal tfb may be a signal indicating a standby time in a specific period.

According to an example embodiment, the feedforward compensators 334 and 434 may receive the position value Ze in the second direction of the error signal or the position value Ye in the third direction of the error signal and may output the feedforward signal Xff. In this case, the feedforward signal Xff may be a signal indicating a position compensation value in the first direction compensating for the position value Xs in the first direction of the determination signal in a specific period.

First, referring to FIG. 7, the feedforward compensator 334 may feedforward compensate the position value Ye in the third direction of the error signal and may generate and output the feedforward signal Xff. The feedforward signal Xff may be a value changing the position value

Xs in the first direction of the determination signal using the position value Ye in the third direction of the error signal. For example, the feedforward signal Xff may be a value generated from the position value Ye in the third direction of the error signal and may be added to the position value

Xs of the determination signal to generate a new position value of the determination signal. The position value Xs and the new position value may be a x-coordinate value from the origin O as shown in FIG. 6. Accordingly, the position in the first direction in which a droplet of the next specified period is to be irradiated with the laser beam may be changed.

Referring to FIG. 8, the feedforward compensator 434 may feedforward compensate the position value Ze in the second direction of the error signal and may generate and output the feedforward signal Xff. The feedforward signal Xff may be a value changing the position value Xs in the first direction of the determination signal using the position value Ze in the second direction of the error signal. For example, the feedforward signal Xff may be a value generated from the position value Ze in the second direction of the error signal and may be added to the position value Xs of the determination signal to generate a new position value of the determination signal. The position value Xs and the new position value may be a x-coordinate value from the origin O as shown in FIG. 6. Accordingly, the position in the first direction in which a droplet of the next specified period is to be irradiated with the laser beam may be changed.

Referring to FIG. 7 and FIG. 8, the controllers 330 and 430 may determine the signal obtained by adding the feedback signal tfb to the reference signal tref as an oscillation time point tfr. In other words, the oscillation time point tfr may be a time point after the standby time from the reference time point.

The controllers 330 and 430 may control the light source generator 310, 410 to emit a laser beam at the oscillation time point tfr. The controllers 330 and 430 may repeat the previously described processes, such as calculating a measurement signal using an output of the position sensors 320 and 420 when a droplet is irradiated with the laser beam.

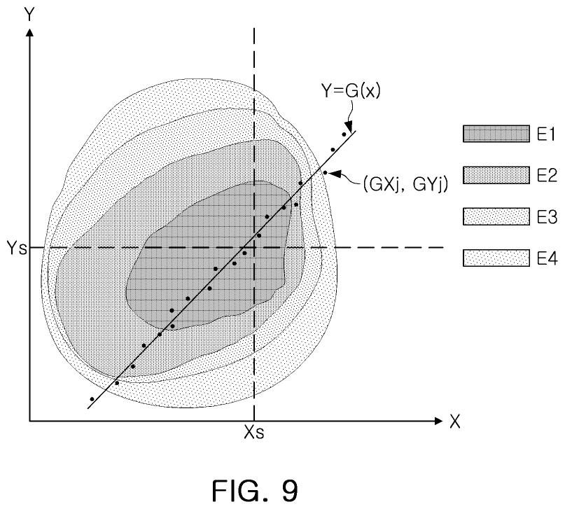

FIG. 9 is a diagram illustrating a compensation function included in a feedforward compensator according to an example embodiment.

The semiconductor process apparatus may include a droplet supplier, a light source generator, a position sensor, and a controller. The controller may include a feedback controller and a feedforward compensator. Specific example embodiments of the semiconductor process apparatus may be similar to the examples described with reference to FIGS. 1 to 7. In an embodiment, each of the feedback controller and the feedforward compensator may correspond to software functional blocks running on the controller. In an embodiment, each of the feedback controller and the feedforward compensator may correspond to a functional circuit block which performs an operation as described below. In an embodiment, each of the feedback controller and the feedforward compensator may be a hybrid functional bock in which a portion of the operation performed by each of the feedback controller and the feedforward compensator is implemented using a software functional block and the other is implemented as a functional circuit block.

According to an example embodiment, the feedforward compensator may include a compensation function G. The compensation function G in an example embodiment illustrated in FIG. 9 may correspond to a linear function. That is, the feedforward compensator may be a linear system. However, an example embodiment thereof is not limited thereto, and the feedforward compensator may correspond to a non-linear system, a static system, or a dynamic system.

FIG. 9 may indicate dispersion of energy of extreme ultraviolet light for the position value in the X-axis direction and the position value in the Y-axis direction of the measurement signal. The dispersion of energy of extreme ultraviolet light may be illustrated in the order of a first region E1, a second region E2, a third region E3, and a fourth region E4, in the order of a higher energy. The dispersion of energy of extreme ultraviolet light may include a plurality of pieces of energy data {Xi, Yi, Ei}, and i may be a positive integer referring to each droplet supplied by the droplet supplier 120.

The compensation function G in an example embodiment illustrated in FIG. 9 may be calculated from the dispersion of energy of extreme ultraviolet light for a semiconductor process apparatus not including a feedforward compensator. In other words, the semiconductor process apparatus may determine the oscillation time point by feedback-controlling only the position value in the first direction of the error signal, and may not feedforward-compensate for the position value in the third direction of the error signal.

A plurality of pieces of energy data {Xi, Yi, Ei} may be divided into N number of groups, and N may be 20 in the example embodiment illustrated in FIG. 9. For each of the N number of groups, a plurality of pieces of energy group data {GXj, GYj} may be calculated, and j may be a positive integer corresponding to the order of the N number of groups. GXj may be calculated by equation 1.

$$GXj = {min}_{i} Xi + ( j - 0.5 ) \times \frac{{max}_{i} Xi - {min}_{i} Xi}{N} \qquad [ Equation l ]$$

The interval between the maximum and minimum values of Xi among a plurality of pieces of energy data may be divided into N number of a plurality of X sections having the same interval on the X-axis. For each of the N plurality of X sections, GXj may correspond to a middle value of each of the N plurality of X sections. Gyj may be calculated by equation 2 to equation 4.

$$Ij = \{ i \vert Xi ϵ [ GXj - \frac{\begin{matrix}max \\ i\end{matrix} Xi - \begin{matrix}min \\ i\end{matrix} Xi}{2 N} , GXj + \frac{\begin{matrix}max \\ i\end{matrix} Xi - \begin{matrix}min \\ i\end{matrix} Xi}{2 N} ] \} \qquad [ Equation 2 ]$$

$$\begin{matrix}Sj = argmax Ei \\ iϵIj\end{matrix} \qquad [ Equation 3 ]$$

$$GYj = Yi \vert ( i = Sj ) \qquad [ Equation 4 ]$$

For each of the N plurality of X sections, Gyj may correspond to Yi corresponding to Xi among {Xi} included in each of the N plurality of X sections in which extreme ultraviolet light has the maximum energy.

As an example embodiment illustrated in FIG. 9, compensation function G may be a primary function of Y with respect to X calculated by linearly fitting {GXj, Gyj}. In other words, the compensation function G may be a linear function which fits position values in the Y-axis direction in which extreme ultraviolet light has the maximum energy with respect to position values in the X-axis direction.

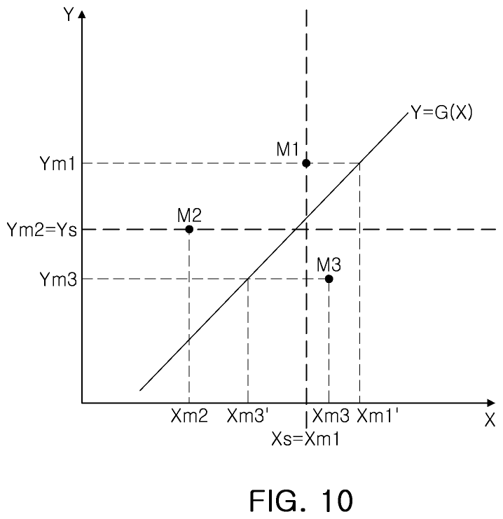

FIG. 10 is a diagram illustrating application of a compensation function according to an example embodiment illustrated in FIG. 9.

The semiconductor process apparatus may include a droplet supplier, a light source generator, a position sensor, and a controller. The controller may include a feedback controller and a feedforward compensator. The feedforward compensator may include a compensation function G. Specific example embodiments of the semiconductor process apparatus may be similar to the examples described with reference to FIGS. 1 to 7.

FIG. 10 may represent a compensation function G corresponding to a relationship between a maximum energy at a position value in the Y-axis and a position value in the X-axis as shown in FIG. 9, and the compensation function G may be a linear function for a position value in the Y-axis direction in which extreme ultraviolet light has maximum energy with respect to a position value in the X-axis direction of a measurement function.

FIG. 10 may illustrate a position value Xs in the X-axis direction of a determination signal and a position value Ys in the Y-axis direction together. Each of the position value Xs in the X-axis direction and the position value Ys in the Y-axis direction of the determination signal may be a positive number and/or a negative number. Alternatively, at least one of the position value Xs in the X-axis direction and the position value Ys in the Y-axis direction of the determination signal may be 0.

In the first specific period, the laser beam may be irradiated to the first droplet in the first position M1. The measurement signal for the first droplet may include a position value Xm1 in the X-axis direction and a position value Ym1 in the Y-axis direction. The position value Xm1 in the X-axis direction of the measurement signal for the first droplet may be the same as the position value Xs in the X-axis direction of the determination signal.

The position value in the Y-axis direction of the error signal for the first droplet may be a difference between Ys and Ym1. In the position value Ym1 in the Y-axis direction of the measurement signal for the first droplet, the position value in the X-axis direction in which extreme ultraviolet light has maximum energy may be Xm1′. The feedforward compensator may calculate the difference value of Xm1′ with respect to Xm1 in the X-axis direction of the determination signal as a position compensation value in the first direction.

In the second specific period, the second droplet at the second position M2 may be irradiated with a laser beam. The measurement signal for the second droplet may include the position value Xm2 in the X-axis direction and the position value Ym2 in the Y-axis direction. The position value Ym2 in the Y-axis direction of the measurement signal for the second droplet may be the same as the position value Ys in the Y-axis direction of the determination signal.

The position value in the Y-axis direction of the error signal for the second droplet may be 0. In other words, extreme ultraviolet light may have maximum energy at the position value Ym2 in the Y-axis direction of the measurement signal for the second droplet. That is, the feedforward compensator may calculate the position compensation value in the first direction as 0.

In the third specific period, a laser beam may be irradiated to a third droplet in a third position M3. The measurement signal for the third droplet may include a position value Xm3 in the X-axis direction and a position value Ym3 in the Y-axis direction.

The position value in the Y-axis direction of the error signal for the third droplet may be a difference between Ys and Ym3. In the position value Ym3 in the Y-axis direction of the measurement signal for the third droplet, the position value in the X-axis direction in which extreme ultraviolet light has the maximum energy may be Xm3′. The feedforward compensator may calculate the difference value of the position value Xs in the X-axis direction of the determination signal to Xm3′ as a position compensation value in the first direction.

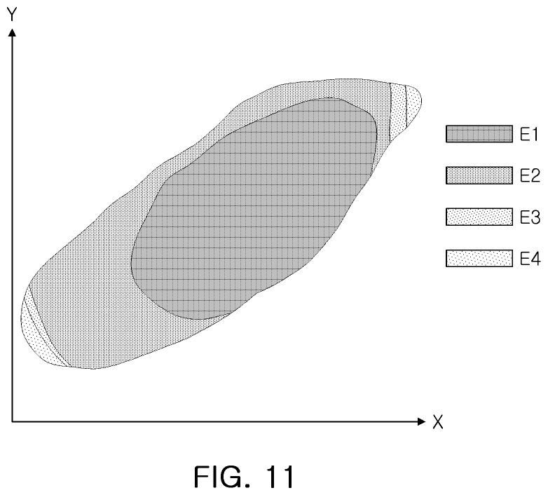

FIG. 11 is a diagram illustrating dispersion of energy of extreme ultraviolet light output by a light source generator including a compensation function according to an example embodiment illustrated in FIG. 9.

The semiconductor process apparatus may include a light source generator and a controller. Specific example embodiments of the semiconductor process apparatus may be similar to the examples described with reference to FIGS. 1 to 6.

According to an example embodiment, the controller may calculate a position compensation value in the first direction using a position value in the third direction of an error signal. The controller may determine an oscillation time point using a position value in the first direction and a position compensation value in the first direction of a determination signal. Specific example embodiments thereof may be similar to the examples described with reference to FIGS. 7, 9, and 10.

FIG. 11 may be a diagram illustrating dispersion of energy of extreme ultraviolet light according to an example embodiment. The dispersion of energy of extreme ultraviolet light will be described according to an example embodiment and a comparative example with reference to FIG. 9 together. FIG. 9 is a diagram illustrating dispersion of energy of extreme ultraviolet light according to a comparative example, and may correspond to the dispersion of energy of extreme ultraviolet light in which a position compensation value in the first direction is not calculated using the position value in the third direction of the error signal.

FIG. 9 and FIG. 11 may represent dispersion of energy of extreme ultraviolet light for a position value in the X-axis direction and a position value in the Y-axis direction of a measurement signal. The energy of extreme ultraviolet light may be illustrated in the order of a first region E1, a second region E2, a third region E3, and a fourth region E4, in order of higher energy.

The dispersion of energy of extreme ultraviolet light according to an example embodiment may be lower than the dispersion of energy of extreme ultraviolet light according to a comparative example. The average energy of extreme ultraviolet light according to an example embodiment may be higher than the average energy of extreme ultraviolet light according to a comparative example. Accordingly, the semiconductor process time may be shortened, and productivity may be improved.

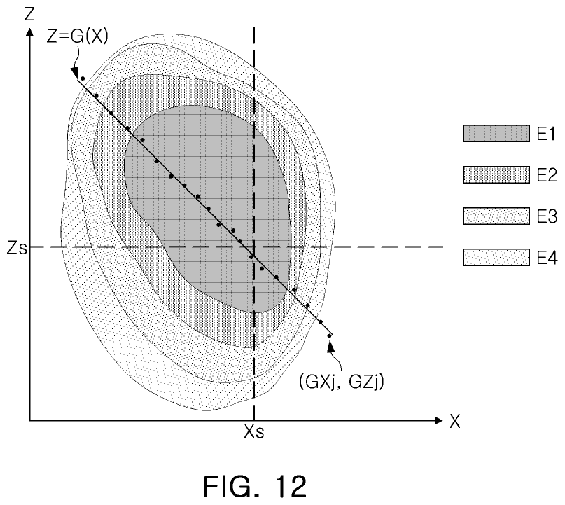

FIG. 12 is a diagram illustrating a compensation function included in a feedforward compensator according to an example embodiment.

The semiconductor process apparatus may include a droplet supplier, a light source generator, a position sensor, and a controller. The controller may include a feedback controller and a feedforward compensator. Specific example embodiments of the semiconductor process apparatus may be similar to the examples described with reference to FIGS. 1 to 6, and FIG. 8.

According to an example embodiment, the feedforward compensator may include a compensation function G. The compensation function G in an example embodiment illustrated in FIG. 12 may correspond to a linear function. That is, the feedforward compensator may be a linear system. However, an example embodiment thereof is not limited thereto, and the feedforward compensator may correspond to a nonlinear system, a static system, or a dynamic system.

FIG. 12 may indicate the dispersion of energy of extreme ultraviolet light with respect to a position value in the X-axis direction and a position value in the Z-axis direction of a measurement signal. The dispersion of energy of extreme ultraviolet light may be illustrated in the order of the first region E1, the second region E2, the third region E3, and the fourth region E4, in order of higher energy. The dispersion of energy of extreme ultraviolet light may include a plurality of pieces of energy data {Xi, Zi, Ei}, in which i may be a positive integer referring to each droplet supplied by the droplet supplier 120.

The compensation function G in an example embodiment illustrated in FIG. 12 may be calculated from the dispersion of energy of extreme ultraviolet light for a semiconductor process apparatus not including a feedforward compensator. In other words, the semiconductor process apparatus may determine an oscillation time point by feedback controlling only the position value in the first direction of the error signal, and may not feedforward-compensate for the position value in the second direction of the error signal.

The plurality of pieces of energy data {Xi, Zi, Ei} may be divided into N number of groups, and N may be 20 in the example embodiment illustrated in FIG. 12. For each of the N number of groups, a plurality of pieces of energy group data {GXj, GZj} may be calculated, and j may be a positive integer corresponding to the order of the N number of groups. GXj may be calculated by equation 1 described with reference to FIG. 9. GZj may be calculated by equation 2, equation 3, and equation 5 described with reference to FIG. 9.

$$GZj = Zi \vert ( i = Sj ) \qquad [ Equation 5 ]$$

For each of the N plurality of X sections, GZj may correspond to Zi corresponding to Xi among {Xi} included in each of the N plurality of X sections in which extreme ultraviolet light has the maximum energy.

As an example embodiment illustrated in FIG. 12, the compensation function G may be a primary function for Z with respect to X calculated by linearly fitting {GXj, GZj}. In other words, the compensation function G may be a linear function which fits the position value in the Z-axis direction in which extreme ultraviolet light has the maximum energy to the position value in the X-axis direction.

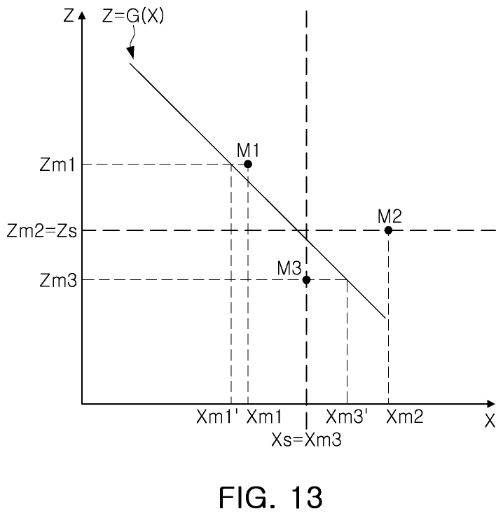

FIG. 13 is a diagram illustrating application of a compensation function according to an example embodiment illustrated in FIG. 9.

The semiconductor process apparatus may include a droplet supplier, a light source generator, a position sensor, and a controller. The controller may include a feedback controller and a feedforward compensator. The feedforward compensator may include a compensation function

G. Specific example embodiments of the semiconductor process apparatus may be similar to the examples described with reference to FIGS. 1 to 6, and FIG. 8.

FIG. 13 may indicate a compensation function G which is a relationship between a maximum energy at a position value in the X-axis and a position value in the X-axis as shown in FIG. 12. In an embodiment, the compensation function G may be a linear function for a position value in the Z-axis direction in which extreme ultraviolet light has maximum energy with respect to a position value in the X-axis direction of a measurement function.

FIG. 13 may illustrate a position value Xs in the X-axis direction of a determination signal and a position value Zs in the Z-axis direction together. Each of the position value Xs in the X-axis direction and the position value Zs in the Z-axis direction of the determination signal may be positive and/or negative. Alternatively, at least one of the position value in the X-axis direction Xs and the Z-axis direction position value Zs of the determination signal may be 0.

In the first specific period, the laser beam may be irradiated to the first droplet in the first position M1. The measurement signal for the first droplet may include the X-position value Xm1 in the axis direction and the position value Zm1 in the Z-axis direction.

The Z-axis direction position value of the error signal for the first droplet may be a difference between Zs and Zm1. In relation to the position value Zm1 in the Z-axis direction of the measurement signal for the first droplet, the position value in the X-axis direction in which extreme ultraviolet light has maximum energy may be Xm1′. The feedforward compensator may calculate a difference value of the position value in the X-axis direction Xs of the determination signal to Xm1′ as a position compensation value in the first direction.

In the second specific period, the second droplet in the second position M2 may be irradiated with a laser beam. The measurement signal for the second droplet may include the position value Xm2 in the X-axis direction and the position value Zm2 in the Z-axis direction. The position value Zm2 in the Z-axis direction of the measurement signal for the second droplet may be the same as the position value Zs in the Z-axis direction of the determination signal.

The position value in the Z-axis direction of the error signal for the second droplet may be 0. In other words, since the maximum energy of extreme ultraviolet light is formed in the position value Zm2 in the Z-axis direction of the measurement signal for the second droplet, it may not be necessary to change the oscillation point in time. That is, the feedforward compensator may calculate the position compensation value in the first direction as 0.

In the third specific period, the third droplet in the third position M3 may be irradiated with a laser beam. The measurement signal for the third droplet may include the position value Xm3 in the X-axis direction and the position value Zm3 in the Z-axis direction. The position value Xm3 in the X-axis direction of the measurement signal for the third droplet may be the same as the position value Xs in the X-axis direction of the determination signal.

The position value in the Z-axis direction of the error signal for the third droplet may be the difference between Zs and Zm3. In relation to the position value Zm3 in the Z-axis direction of the measurement signal for the third droplet, the position value in the X-axis direction in which extreme ultraviolet light has the maximum energy may be Xm3′. The feedforward compensator may calculate the difference value of the position value Xs in the X-axis direction of the determination signal to Xm3′ as a position compensation value in the first direction.

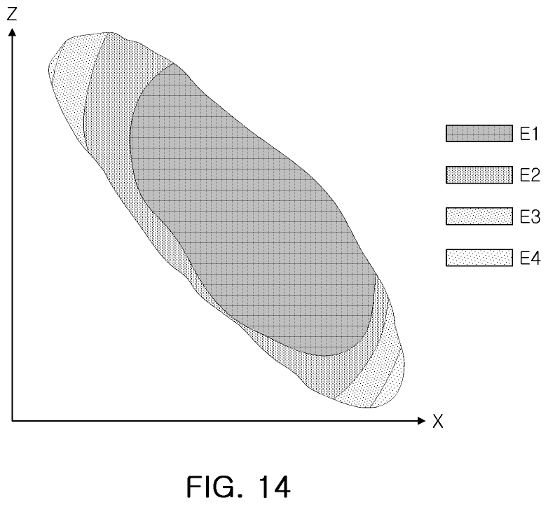

FIG. 14 is a diagram illustrating dispersion of energy of extreme ultraviolet light output by a light source generator including a compensation function according to an example embodiment.

The semiconductor process apparatus may include a light source generator and a controller. Specific example embodiments of the semiconductor process apparatus may be similar to the examples described with reference to FIGS. 1 to 6.

According to an example embodiment, the controller may calculate a position compensation value in the first direction using a position value in the second direction of an error signal. The controller may determine an oscillation time point using a position value in the first direction and a position compensation value in the first direction of a determination signal. Specific example embodiments thereof may be similar to the examples described with reference to FIGS. 8, 12, and 13.

FIG. 14 may be a diagram illustrating dispersion of energy of extreme ultraviolet light according to an example embodiment. The dispersion of energy of extreme ultraviolet light will be described according to an example embodiment and a comparative example with reference to FIG. 12 together. FIG. 12 is a diagram illustrating dispersion of energy of extreme ultraviolet light according to a comparative example, and may correspond to dispersion of energy of extreme ultraviolet light in which a position compensation value in the first direction is not calculated using the position value in the second direction of the error signal.

FIGS. 12 and 14 may indicate dispersion of energy of extreme ultraviolet light for a position value in the X-axis direction and a position value in the Z-axis direction of a measurement signal. The energy of extreme ultraviolet light may be illustrated in the order of a first region E1, a second region E2, a third region E3, and a fourth region E4 in order of higher energy.

The dispersion of energy of extreme ultraviolet light according to an example embodiment may be lower than the dispersion of energy of extreme ultraviolet light according to a comparative example. The average energy of extreme ultraviolet light according to an example embodiment may be higher than the average energy of extreme ultraviolet light according to the comparative example. Accordingly, the semiconductor process time may be shortened, and productivity may be improved.

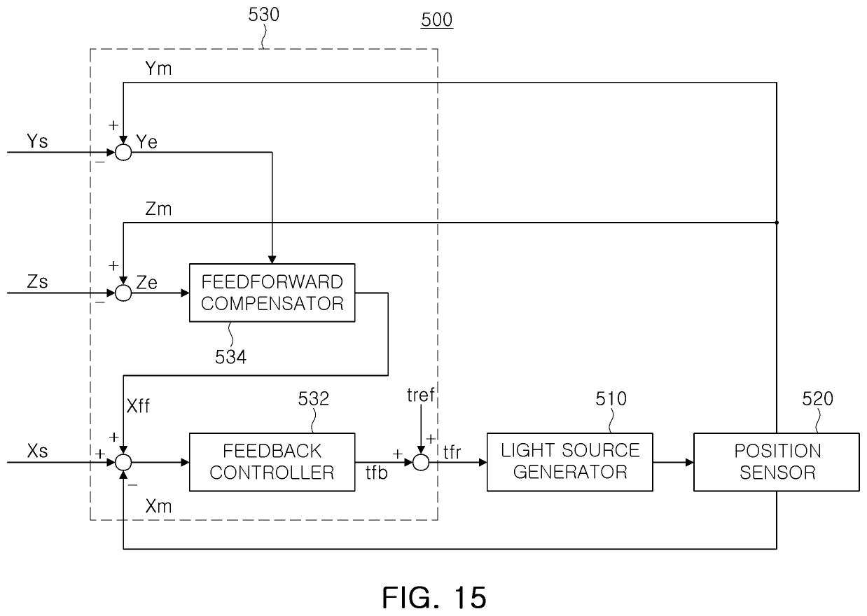

FIG. 15 is a block diagram illustrating a semiconductor process apparatus according to an example embodiment.

The semiconductor process apparatus 500 may include a light source generator 510, a position sensor 520, and a controller 530. The controller 530 may receive a determination signal, may calculate a measurement signal indicating a position at which a droplet is irradiated with a laser beam using an output signal of the position sensor 520, and may calculate an error signal. Specific example embodiments may be similar to the examples described with reference to FIGS. 1 to 6.

According to an example embodiment, the semiconductor process apparatus 500 may include a feedback controller 532 generating a feedback signal tfb and a feedforward compensator 534 generating a feedforward signal Xff.

The feedback controller 532 may receive a feedforward signal Xff in a specific period, a position value Xs in the first direction of the determination signal, and a position value Xm in the first direction of the measurement signal, and may output a feedback signal tfb. In other words, the feedback controller 532 may generate a feedback signal tfb by feedback-controlling a signal obtained by adding a feedforward signal Xff to the difference between the position value Xs in the first direction of the determination signal and the position value Xm in the first direction of the measurement signal in a specific period. In this case, the feedback signal tfb may be a signal indicating a standby time in a specific period.

The feedforward compensator 534 of the semiconductor process apparatus 500 may be different from the feedforward compensators 334 and 434 of the semiconductor process apparatuses 300 and 400 illustrated in FIGS. 7 and 8 in that the feedforward compensator 534 may generate the feedforward signal Xff by using both the position value Ze in the second direction and the position value Ye in the third direction of the error signal. In this case, the feedforward signal Xff may be a signal indicating the position compensation value in the first direction in a specific period.

Referring to FIG. 15, the feedforward compensator 534 may feedforward-compensate the position value Ze in the second direction and the position value Ye in the third direction of the error signal and may generate and output the feedforward signal Xff. The feedforward signal Xff may be a value changing the position value Xs in the first direction of the determination signal using the position value Ze in the second direction and the position value Ye in the third direction of the error signal. Accordingly, the position in the first direction in which the droplet is irradiated with the laser beam may be changed.

As compared to FIGS. 7 and 8, the feedforward compensator 534 in FIG. 15 may change the position value Xs in the first direction of the determination signal using the position value Ze in the second direction and the position value Ye in the third direction of the error signal, such that the position in the first direction in which the droplet is irradiated with the laser beam may be controlled precisely. Accordingly, the extreme ultraviolet light may be swiftly controlled to have maximum energy, and the dispersion of energy of extreme ultraviolet light may be swiftly reduced.

The feedforward compensator 534 in FIG. 15 may include a compensation function, and the compensation function may be a multivariable function or a multiple input single output system (MISO-system) for the position value in the X-axis direction, the position value in the Y-axis direction, and the position value in the Z-axis direction having the maximum energy of extreme ultraviolet light.

The controller 530 may determine a signal obtained by adding a feedback signal tfb to a reference signal tref as an oscillation time point tfr. In other words, the oscillation time point tfr may be a time point after a standby time from the reference time point.

The controller 530 may control the light source generator 510 to emit a laser beam at the oscillation time point tfr. The controller 530 may repeat the above-described processes, such as calculating a measurement signal using an output of the position sensor 520 when a droplet is irradiated with the laser beam.

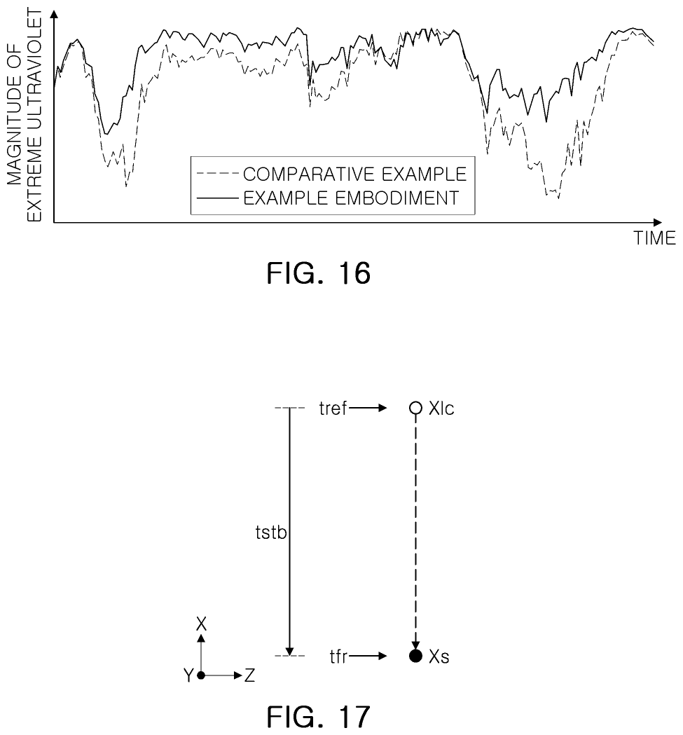

FIG. 16 is a diagram illustrating magnitude of energy of extreme ultraviolet light according to an example embodiment.

A semiconductor process apparatus according to an example embodiment may calculate a position compensation value in the first direction using at least one of a position value in the second direction of an error signal and a position value in the third direction of an error signal. The semiconductor process apparatus may determine an oscillation time point using the position value in the first direction of a determination signal, the position value in the first direction of a measurement signal, and the position compensation value in the first direction. Accordingly, the position value in the first direction in which a droplet is irradiated with a laser beam may be controlled.

A semiconductor process apparatus according to an example embodiment and a comparative example of the present disclosure may calculate an oscillation time point using the position value in the first direction of an error signal and may not reflect the position value in the second direction of the error signal and the position value in the third direction of the error signal to the oscillation time point. In other words, the semiconductor process apparatus may not calculate the position compensation value in the first direction.

FIG. 16 may represent magnitude of extreme ultraviolet light energy (EUV Energy) according to time. The unit of time may be seconds(s), and the unit of extreme ultraviolet light magnitude of energy may be millijoule (mJ).

The maximum energy of extreme ultraviolet light according to an example embodiment may be greater than the maximum energy of extreme ultraviolet light according to a comparative example. The difference between the maximum energy and the minimum energy of extreme ultraviolet light according to the example embodiment may be smaller than the difference between the maximum energy and the minimum energy of extreme ultraviolet light according to the comparative example. The average energy of extreme ultraviolet light according to the example embodiment may be greater than the average energy of extreme ultraviolet light according to the comparative example. That is, the dispersion of energy of extreme ultraviolet light according to an example embodiment may be smaller than the dispersion of energy of extreme ultraviolet light according to the comparative example. Accordingly, the semiconductor process time may be shortened, thereby improving productivity.

FIG. 17 is a diagram illustrating calculation of an oscillation time point according to an example embodiment.

According to an example embodiment, a semiconductor process apparatus may include a chamber, a droplet supplier, a light source generator, a position sensor, a laser-beam curtain generator, and a laser-beam curtain sensor as an apparatus for performing a photolithography process. Specific example embodiments of the semiconductor process apparatus may be similar to the examples described with reference to FIGS. 1 to 16 above.

According to an example embodiment, the laser-beam curtain generator may emit a laser beam curtain in the second direction (the Z-axis direction in FIG. 17). Differently from the light source generator configured to emit a laser beam at an oscillation point in time, the laser-beam curtain generator may continuously emit a laser beam curtain while the semiconductor process is performed.

Referring to FIG. 2, the droplet supplier may form a droplet and may supply the droplet to an internal region of the chamber in the first direction (the −X-axis direction in FIG. 17). In other words, the droplet may move in the first direction. The laser-beam curtain sensor may sense the laser beam curtain reflected from the droplet when the droplet passes through the laser beam curtain.

The point at which the droplet passes through the laser beam curtain may be determined in advance. The point at which the droplet passes through the laser beam curtain may be controlled to be constant while the semiconductor process is performed. As an example embodiment illustrated in FIG. 17, the point at which the droplet passes through the laser beam curtain may have a position value in the first direction Xlc.

As for the position value in the first direction of the droplet passing through the laser beam curtain, the controller may determine the time point at which the laser-beam curtain sensor senses the laser beam curtain reflected from the droplet as a reference time point tref.

The controller may calculate the time period required from the point at which the droplet passes through the laser beam curtain to reach the position value Xs in the first direction of the determination signal as a standby time tstb. The controller may calculate the standby time tstb using the relationship between the distance between the position value in the first direction Xlc of the point at which the droplet passes through the laser beam curtain and the position value Xs in the first direction of the determination signal and the moving speed of the droplet.

The controller may calculate the time point after the standby time tstb from the reference time point tref as the oscillation time point tfr. The light source generator may emit a laser beam in the second direction at the oscillation time point tfr, such that the laser beam may be irradiated to the droplet and extreme ultraviolet light may be formed.

The process of calculating the oscillation time point tfr may be repeated in specific periods. For example, the specific period may be a period in which the droplet is discharged, but an example embodiment thereof is not limited thereto.

According to the aforementioned example embodiments, by controlling the oscillation time point at which a light source generator included in the light source system of the semiconductor process apparatus emits a laser beam, the position value in the first direction at which a droplet is irradiated with the laser beam may be controlled. Accordingly, the average size of the energy of extreme ultraviolet light generated from the droplet may be improved, and the dispersion of energy of the extreme ultraviolet light may be reduced.

While the example embodiments have been illustrated and described above, it will be configured as apparent to those skilled in the art that modifications and variations could be made without departing from the scope of the present disclosure as defined by the appended claims.

What is claimed is:

1. A semiconductor process apparatus comprising:
a droplet supplier configured to form a first droplet and to supply the first droplet to a chamber in a first direction and in a first specific period;
a light source generator configured to emit a laser beam in a second direction perpendicular to the first direction at a first emission time point such that extreme ultraviolet light is generated from the first droplet;
a position sensor disposed adjacently to the chamber; and
a controller configured to:
receive a determination signal including a first information representing a first position at which the laser beam is expected to irradiate the first droplet;
calculate a second position at which the laser beam irradiates the first droplet using an output of the position sensor and generate a measurement signal including a second information representing the second position;
generate at least one of a first error signal and a second error signal from the determination signal and the measurement signal;
generate a feedforward signal from at least one of the first error signal and the second error signal;
generate a feedback signal from the feedforward signal and a first position difference in the first direction between the first position and the second position; and
determine a second emission time point for a second specific period in which the droplet supplier supplies a second droplet into the chamber by adding the feedback signal to a reference signal including an information representing a reference time point in the first specific period.

2. The semiconductor process apparatus of claim 1,
wherein the controller is configured to calculate a position difference between the first position and the second position to generate the at least one of the first error signal and the second error signal,
wherein each of the first position of the determination signal and the second position of the measurement signal includes a first position value in the first direction, a second position value in the second direction, and a third position value in a third direction perpendicular to the first direction and the second direction,
wherein the position difference includes the first position difference in the first direction, a second position difference in the second direction and a third position difference in the third direction, and
wherein the first error signal includes an information representing the second position difference and the second error signal includes an information representing the third position difference.

3. The semiconductor process apparatus of claim 1,
wherein the laser beam includes a first laser beam and a second laser beam, and
wherein, after the first laser beam irradiates the first droplet, the second laser beam irradiates the first droplet.

4. The semiconductor process apparatus of claim 3,
wherein the determination signal includes the first information representing the first position at which the first laser beam is expected to irradiate the first droplet, and
wherein the measurement signal includes the second information representing the second position at which the first laser beam irradiates the first droplet.

5. The semiconductor process apparatus of claim 3,
wherein the determination signal includes the first information representing the first position at which the second laser beam is expected to irradiate the first droplet, and
wherein the measurement signal includes the second information representing the second position at which the second laser beam irradiates the first droplet.

6. The semiconductor process apparatus of claim 1,
wherein the feedforward signal includes a position compensation value in the first direction to adjust a position value in the first direction of the determination signal in the first specific period.

7. The semiconductor process apparatus of claim 1,
wherein the feedback signal includes information representing a standby time in the first specific period.

8. The semiconductor process apparatus of claim 7,
wherein the second emission time point is a time point after the standby time from the reference time point.

9. The semiconductor process apparatus of claim 2, further comprising:
a laser-beam curtain generator configured to form a laser beam curtain at a plane defined by the second direction and the third direction; and
a laser-beam curtain sensor configured to sense the laser beam curtain reflected from the first droplet when the first droplet passes through the laser beam curtain.

10. The semiconductor process apparatus of claim 9,
wherein the controller is configured to determine a time point at which the laser-beam curtain sensor senses the laser beam curtain reflected from the first droplet as a reference time point.

11. The semiconductor process apparatus of claim 10,
wherein the reference signal includes an information representing the reference time point in the first specific period.

12. The semiconductor process apparatus of claim 1,
wherein the first droplet is emitted in the first specific period.

13. The semiconductor process apparatus of claim 1,
wherein the position sensor includes at least one of a quad-cell sensor and an image sensor.

14. A semiconductor process apparatus comprising:
a droplet supplier configured to form a droplet and to supply the droplet to a chamber in a first direction;
a light source generator configured to emit a laser beam in a second direction perpendicular to the first direction at a first emission time point such that extreme ultraviolet light is generated from the droplet;
a position sensor disposed adjacently to the chamber; and
a controller configured to receive a determination signal including an information representing a first position at which the droplet is determined to be irradiated with the laser beam and to determine a second emission time point,
wherein the controller is further configured to calculate a measurement signal including an information representing a second position at which the droplet is irradiated with the laser beam using an output of the position sensor, and to generate an error signal including an information representing a difference between the first position of the determination signal and the second position of the measurement signal,
wherein the determination signal, the measurement signal, and the error signal include position values in the first direction, the second direction, and a third direction perpendicular to the first direction and the second direction in a specific period, respectively,
wherein the controller is further configured to calculate a position compensation value in the first direction using at least one of a position value in the second direction of the error signal and a position value in the third direction of the error signal, and
wherein the second emission time point is determined using a position value in the first direction of the determination signal, a position value in the first direction of the measurement signal, and a position compensation value in the first direction.

15. The semiconductor process apparatus of claim 14, further comprising:
a laser-beam curtain generator configured to form a laser beam curtain at a plan defined by the second direction and the third direction; and
a laser-beam curtain sensor configured to sense the laser beam curtain reflected from the droplet when the droplet passes through the laser beam curtain.

16. The semiconductor process apparatus of claim 15,
wherein the controller is further configured to determine a time point at which the laser-beam curtain sensor senses the laser beam curtain reflected from the droplet as a reference time point.

17. The semiconductor process apparatus of claim 16,
wherein the controller is further configured to calculate a standby time using a moving speed of the droplet and a distance in the first direction between a first position in the first direction at which the droplet passes through the laser beam curtain and a second position in the first direction obtained by adding a position value in the first direction of the determination signal to the position compensation value in the first direction.

18. The semiconductor process apparatus of claim 17,
wherein the second emission time point is a time point after the standby time from the reference time point.

19. The semiconductor process apparatus of claim 14,
wherein the droplet is discharged in the specific period.

20. A semiconductor process apparatus comprising:
a droplet supplier configured to form a droplet and to supply the droplet to a chamber in a first direction;
a light source generator configured to emit a laser beam in a second direction perpendicular to the first direction at a first emission time point such that extreme ultraviolet light is generated from the droplet;
a position sensor disposed adjacently to the chamber; and
a controller configured to receive a determination signal including an information representing a first position at which the droplet is determined to be irradiated with the laser beam and to determine a second emission time point,
wherein the controller is further configured to calculate a measurement signal including an information representing a second position at which the droplet is irradiated with the laser beam using an output of the position sensor, and to calculate an error signal including an information representing a difference between the first position of the determination signal and the second position of the measurement signal,
wherein the determination signal, the measurement signal, and the error signal include position values in the first direction, the second direction, and a third direction perpendicular to the first direction and the second direction in a specific period, respectively, and
wherein a position value in the first direction of the determination signal is controlled such that energy of extreme ultraviolet light increases at a position value in the second direction of the measurement signal and at a position value in the third direction of the measurement signal by determining the second emission time point using position values in the first to third directions of the error signal.
